(19) United States
(12) Patent Application Publication
(10) Pub. No.: US 2007/0202628 A1
(43) Pub. Date: Aug. 30, 2007

(54) Manufacturing process for integrated piezo elements

(75) Inventor: Alida Wuertz, Marbach (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/710,551

(22) Filed: Feb. 26, 2007

(30) Foreign Application Priority Data
Feb. 24, 2006 (DE) 102006008584.1-33

(51) Int. Cl. H01L 21/00

(52) U.S. Cl. 438/53

(57) ABSTRACT

A method is provided for the production of integrated microelectromechanical elements, in which first a silicon layer is formed on an insulation layer, then a piezoresistive layer on or in the silicon layer, and then at least one etch opening for etching at least one cavity substantially within the silicon layer. The shape of the cavity in the silicon layer is predefined by arrangement of additional vertical and horizontal etch stop layers, and the etching process is readily reproducible. The method is suitable for being integrated into standard fabrication processes particularly with circuit components needed for signal conditioning and signal processing.

This nonprovisional application claims priority under 35 U.S.C. § 119(a) on German Patent Application No. DE 102006008584, which was filed in Germany on Feb. 24, 2006, and which is herein incorporated by reference.

### BACKGROUND OF THE INVENTION

1. Field of the Invention

The present invention relates to a method for the production of integrated micro-electromechanical elements and to microelectromechanical elements.

2. Description of the Background Art

Microelectromechanical systems MEMS, with which physical parameters such as pressure, force, acceleration, flow, etc., can be converted to an electrical signal, are known. Conversely, it is also known to convert electrical signals, for example, by displacement of a self-supporting membrane into mechanical motion.

The production of different components such as sensors, micromechanical switches, or sound sources with the use of the technology as is used in semiconductor manufacture is also known. Inter alia, sensors are produced in this case, which are also based on a deformable membrane with piezoresistors disposed thereon. For example, an absolute pressure relative to a reference pressure established within a closed cavity below the membrane can be detected with these sensors.

A force, which leads to a charge shift in the piezoelectric body and thereby to a voltage drop or change in resistance across the body, is exerted on the piezoelectric body by deformation of the membrane.

Conversely, the application of an electrical voltage to a piezoelectric body causes its geometric deformation. The achieved motion depends on the polarity of the applied voltage and the direction of the polarization vector.

Primarily the geometry of the membrane and the disposition, form, and nature of piezoresistors are therefore given particular attention in the production of micromechanical elements with membranes and piezoresistors.

Microelectromechanical sensors, which are based on a deformable membrane of silicon nitride with polysilicon piezoresistors, are known from the Proceedings of SPIE, Volume 2642, of the Micromachining and Microfabrication Symposiums, Oct. 23-24, in Austin, Tex. An absolute pressure can be measured with sensors based on the reference pressure in the cavity below the membrane. All materials and process steps for the production of the sensors can be integrated into a CMOS process. Here, an insulation layer (silicon-nitride layer) on a substrate is formed first. Then, a thick oxide layer (TEOS) and next again a thin oxide layer (BPSG) are applied to the insulation layer; both of these are patterned after application. After this, a nitride layer is applied for the later membrane and also patterned. Next, the two oxide layers below the nitride layer are etched in an HF solution, so that a cavity forms below the nitride layer, and then the etch openings are sealed with nitride. Next, first the piezoresistive polysilicon is applied, implanted, and patterned and then aluminum is applied and patterned.

U.S. Pat. No. 6,959,608 discloses a piezoresistive pressure sensor and a method for its manufacture based on an SOI wafer. Here, first, a narrow gap in the silicon and oxide layer is etched and then the wafer is covered with a nitride layer to fill the gap with nitride. After the rest of the nitride is removed, a layer of doped, epitaxially grown silicon is applied to pattern the piezoresistors and terminals. Next, an aluminum layer is applied and patterned and then a narrow etch opening is produced in the silicon layer to etch a cavity in the oxide layer of the wafer by means of HF. Finally, a layer of oxide (LTO) is applied to the wafer, which is simultaneously used to again seal the etch opening.

A disadvantage of this method is that the etching process within the buried oxide layer can be poorly controlled and reproduced.

### SUMMARY OF THE INVENTION

It is therefore an object of the present invention to provide a method for the production of integrated micro-electromechanical elements and to provide microelectromechanical elements

Accordingly, in an aspect of the invention, the following steps are performed after one another in a method for producing integrated microelectromechanical elements. In the processing of a wafer, first a silicon layer is deposited on an insulation layer and then a piezoresistive layer on the silicon layer or the silicon layer is doped in subregions to create a piezoresistive layer. Next, at least one etch opening is created for etching at least one cavity substantially within the silicon layer.

Alternatively, the sequence of steps can also be performed so that first a silicon layer is deposited on an insulation layer. Next, at least one etch opening is created for etching at least one cavity substantially within the silicon layer, and then a piezoresistive layer is deposited on the silicon layer or the silicon layer is doped in subregions for the formation of the piezoresistive layer.

A self-supporting membrane remains above the cavity after the etching, whose thickness and peak deviation are predetermined by the original thickness of the silicon layer.

This simple fabrication process has the advantage that it can be readily incorporated into standard processes and can be integrated with additional circuit components.

According to an embodiment, deep trenches are formed for lateral limiting, preferably within the silicon layer, which extend down to the insulation layer and are also filled with an insulating material, for example, oxide. This functions as a lateral etching stop in the etching of the cavity due to the high selectivity of the etching medium. Furthermore, they also isolate the individual microelectromechanical elements from one another. It is therefore advantageous to make the trenches circumferential and therefore also to determine the shape of the cavity. It is also possible here to arrange the trenches so that after the etching, several cavities communicate within a microelectromechanical element.

According to an embodiment, the silicon layer, which is preferably a polysilicon, is selectively doped to obtain piezoresistive regions. Alternatively, a doped, implanted polysilicon can be provided as a starting material for the piezoresistive layer or a diffusion-doped polysilicon can be used. It is also possible to use other piezoresistive material such as lead-zirconate-titanate ceramics (PZT) or aluminum nitride.

Furthermore, the invention provides for the patterning of the piezoresistive layer to produce piezoresistors, by means of which the displacement of the self-supporting membranes can be detected, because these change their electrical resistance under the influence of mechanical stress.

Alternatively, for patterning the piezoresistive layer, the piezoresistors can also be formed by selectively doping the polysilicon in subregions, which was used as the starting material for the piezoresistive layer. The individual resistors can be isolated here from one another by p-n junctions.

A further embodiment provides for the deposition of a second insulation layer, for example, of silicon oxide SiO₂ or silicon nitride Si₃N₄ on the silicon layer before the formation of the piezoresistive layer. In this case, very good reproducibility of the etching process results, because the insulation layers act as etching stop layers. The shape of the cavity is predetermined laterally by the vertical trenches, below by the first insulation layer and above by the second insulation layer. Thus, the height and geometry of the cavity are determined by the distance and the shape of the trenches in the sacrificial layers and the thickness of the silicon layer. In this case, the second insulation layer functions as a self-supported membrane after the creation of the cavity. Another advantage of the second insulation layer is that this layer also insulates the piezoresistors, which are disposed on it, from one another. By means of the good control of the sacrificial etching, the properties of the individual elements or sensor elements can be well reproduced on the individual wafer and also from wafer to wafer and batch to batch.

It is also preferred to again seal at least one etch opening. An embodiment of the invention, in addition, provides that during the sealing of the etch openings, a defined internal pressure is created in the cavities, which provides a defined reference pressure during pressure measurements using the microelectromechanical element.

Another embodiment of the method provides that the deposition and patterning of several metallization levels, which are used for electrical contacting of the piezoresistive layer, and the deposition of the dielectric layers lying in-between occur before the creation of a cavity.

It is also advantageous for protection of the piezoresistive layer to provide a cover as a protective layer, preferably of Si₃N₄. On the one hand, the cover protects the piezoresistive structures, if these include a material which would be attacked during the sacrificial etching. On the other hand, the cover acts as a protective layer for the surface of the element from environmental influences during later use. The protective layer can also be patterned in subregions or also removed again in order not to detrimentally affect the mechanical properties of the membrane.

Furthermore, the first insulation layer can be formed on the supporting layer, for example, a substrate. An SOI wafer can therefore be used as a starting material for the method of the invention.

According to another embodiment, four piezoresistors can be connected to form a Wheatstone bridge. An improved sensitivity of the element, for example, during use of the sensor, can be achieved by connection as a half or full bridge (two or four adjustable resistors) and in addition temperature compensation can be made possible. Nonadjustable resistors can be disposed outside the membrane.

MEMS elements with piezoelectric layers are electromechanical transducing components. These are capable of converting mechanical forces such as pressure, elongation, or acceleration into electrical voltage or charge transfer (direct piezo effect) and an electrical voltage into mechanical motion or oscillations (inverse piezo effect). A very wide variety of applications become possible in all fields of technology with the use this effect.

For example, the conversion of electrical voltage into mechanical motion can be used for piezoelectric actuators, e.g., translators, bending elements, and piezo motors for micro- and nanopositioning, laser tuning, active vibration damping, pneumatic valves, etc.

Likewise, the conversion of mechanical forces and accelerations is used for sensors, ignition elements, piezo keypads, generators, or for passive damping. The conversion of acoustic into electrical signals is utilized primarily in sound and ultrasound receivers, during noise analysis, or in acoustic emission spectroscopy.

Furthermore, the conversion of electrical signals into oscillations or acoustic signals can also be used in sound and ultrasound generators, signal generators (buzzers), or conductive ultrasound generators.

The direct and also inverse piezo effect is utilized especially in level or flow measurements, and object detection, medical diagnosis, in high-resolution material identification, or in sonar and echo sounders.

In order to obtain a sufficiently large composite signal or a better signal yield, it has proven advantageous to connect several microelectromechanical elements into an array in a network-like manner.

The invention furthermore provides a microelectromechanical element with an insulation layer, a silicon layer, and a patterned, piezoresistive layer, whereby within the silicon layer a cavity and above the cavity a self-supporting membrane are provided, which are disposed on at least a part of the piezoresistive patterned layer.

According to an embodiment, the microelectromechanical element below the patterned piezoresistive layer has a second insulation layer, which serves as a self-supporting membrane after the formation of the cavity disposed in the silicon layer.

It is understood that the aforementioned features and the features still to be described hereafter can be used not only in the specifically provided combination but also in other combinations or alone, without going beyond the scope of the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1a to 1i each show in a sectional drawing, a sequence of process steps for the fabrication of microelectromechanical elements for use as a piezoresistive pressure sensor according to a first embodiment;

FIGS. 2a to 2i each show in a sectional drawing a sequence of process steps for the fabrication of microelectromechanical elements for use as a piezoresistive pressure sensor according to a second embodiment; and

FIG. 3 shows a top plan view of a microelectromechanical element, which can be used as a pressure sensor.

### DETAILED DESCRIPTION

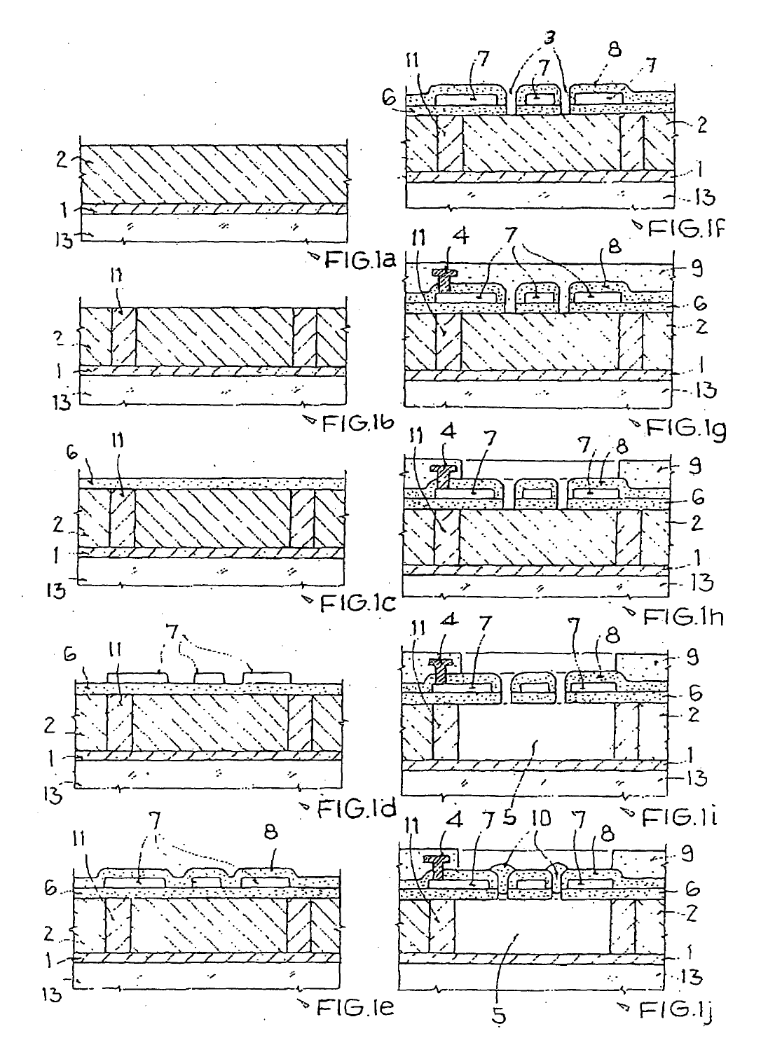

FIG. 1a shows a section through a semiconductor material, for example, an SOI wafer with a first buried insulation layer 1 on a supporting layer 13. A silicon layer 2, which can be both single-crystal and polycrystalline, has been deposited in turn on insulation layer 1. In FIG. 1b, two trenches 11 can be seen, which are used for the lateral isolation of the element from the next element and also to define a later cavity 5. Trenches 11 can be filled on one side with oxide or be made as an oxide liner with a filling of polysilicon or nitride. After the formation of trenches 11, as shown in FIG. 1c, a second insulation layer 6, which includes, for example, silicon nitride Si₃N₄ or silicon oxide SiO₂, is deposited on silicon layer 2 and trench 11. This is used as a micromechanical membrane after sacrificial etching or at least as part of the membrane and for isolation of the individual piezoresistors. The piezoresistors are patterned from a piezoresistive layer 7, which includes, for example, doped, usually implanted polysilicon or another piezoresistive material. Three piezoresistors or parts thereof are evident in FIG. 1d, which are typically connected to one another.

FIG. 1e shows a protective layer 8, which covers the piezoresistive structures. This protective layer, which can also include, for example, silicon nitride Si₃N₄, on the one hand, protects the piezoresistors and the surface of the element from later environmental influences and, on the other, during further processing of the wafer, protects materials, such as doped polysilicon, which would be attacked in later sacrificial etching. Next, etch openings 3 for the sacrificial etching are defined for the formation of cavity 5. It is advantageous to predefine these openings even early in the process, because the later generated topography would make the lithography step during patterning more difficult. FIG. 1g shows the further processing of the wafer in the back-end-of-line (BEOL). In this case, one or more metallization levels with insulating dielectric layers 9 lying in-between are deposited and patterned for contacts and tracks 4.

After the electrical contacting of the wafer, the BEOL, as can be seen in FIG. 1h, is again opened with anisotropic etching and thereby also the already defined etch openings 3 and also the surface of the later sensor are exposed. Next, the sacrificial layer, silicon layer 2 in the present case, is removed by, for example, isotropic etching and a cavity 5 is formed. It becomes clear in FIG. 1i that cavity 5 is limited below by insulation layer 1, at the sides by trenches 11, and above by insulation layer 6, all of which act as an etching stop layer during etching. The height of the cavity and the parameters for the movable membrane are thereby defined by the arrangement of these elements. FIG. 1j shows the sealing of cavity 5 by an optionally patterned layer 10, which is preferably insulated.

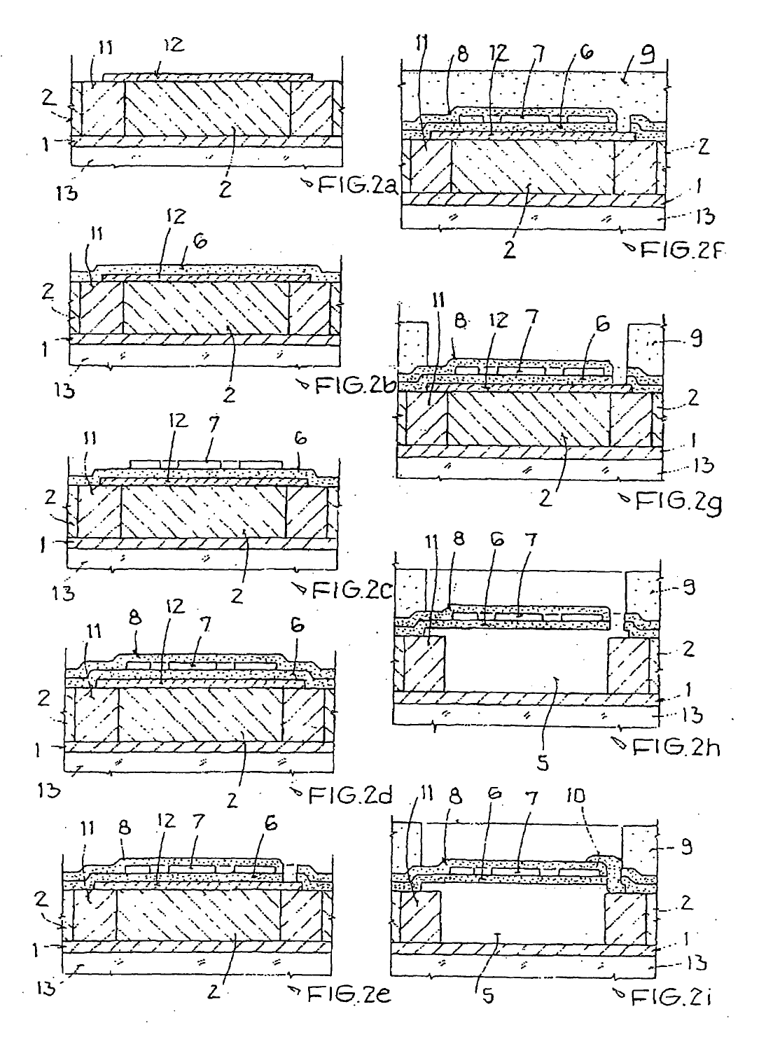

FIGS. 2a to 2i also show the process sequence known from the previous figures. However, as is evident from FIG. 2a, before the deposition of second insulation layer 6, another thin sacrificial layer 12 of polysilicon or similar material is deposited on first conductive layer 2 in subregions. During application of second insulation layer 6, this thin sacrificial layer 12 is completely covered and is again exposed at least at one place only after the application and patterning of piezoresistive layer 7 and its covering with a protective layer 8. FIG. 2f shows the further processing of the wafer. The surface of the later membrane is provided with a cover of one or more insulation layers 9. In the anisotropic etching, part of the cover is again removed to expose the access to sacrificial layer 12. In the following isotropic etching, access to silicon layer 2 is enabled, because sacrificial layer 12 is removed totally or partially. The lower insulation layer 1, trenches 11, and the second insulation layer 6 again function as an etch stop layer. FIG. 2i shows the element with a sealed membrane, whereby seal 10 of etch opening 3 preferably consists of an insulator.

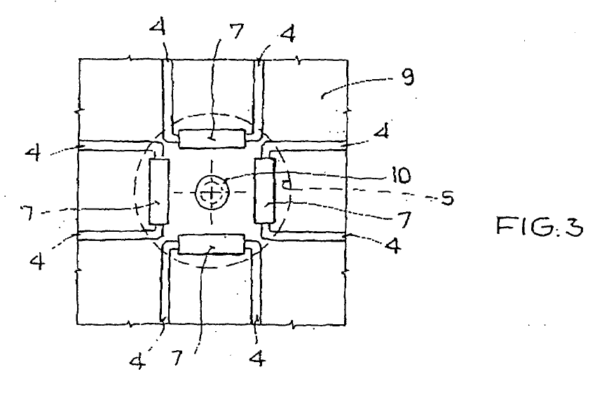

FIG. 3 shows a top plan view of a microelectromechanical element, whereby the covering layer is not shown above the piezoresistors. Four piezoresistors are disposed on the circular membrane, in which the seal 10 of etch openings lies in the middle; these are contacted via tracks 4, which consist of metallization layers or alternatively of doped polysilicon. The form and arrangement of the piezoresistors are variable, in this case, however. For example, the resistors can be designed in such a way that they have a meander-shaped structure or a meander-shaped contour. Furthermore, it is also possible to arrange two opposite resistors rotated 90°.

The oscillation states or forms of the membrane are substantially determined by their geometry and mechanoelastic properties.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for producing integrated microelectromechanical elements, the method comprising:
forming a silicon layer on an insulation layer;
forming a piezoresistive layer on or in the silicon layer; and
forming at least one etch opening for etching at least one cavity substantially within the silicon layer.

2. A method for producing integrated microelectromechanical elements, the method comprising:
first, forming a silicon layer on an insulation layer;
second, forming at least one etch opening for etching at least one cavity substantially within the silicon layer; and
third, forming a piezoresistive layer on or in the silicon layer,
wherein the first, second and third steps are performed sequentially.

3. The method according to claim 1, further comprising the step of forming a trench for laterally limiting the cavity.

4. The method according to claim 3, wherein a circumferential trench is created.

5. The method according to claim 1, wherein, to form the piezoresistive layer, the silicon layer is doped or implanted at least in subregions.

6. The method according to claim 1, wherein a doped or implanted polysilicon is provided as a starting material for the piezoresistive layer.

7. The method according to claim 1, wherein a diffusion-doped polysilicon is provided as a starting material for the piezoresistive layer, at least in subregions.

8. The method according to claim 1, further comprising the step of forming a second insulation layer on the silicon layer before the formation of the piezoresistive layer.

9. The method according to claim 1, further comprising the step of forming piezoresistors by patterning the piezoresistive layer.

10. The method according to claim 1, further comprising the step of forming piezoresistors by selective doping of the silicon layer, wherein the silicon layer is polysilicon.

11. The method according to claim 1, wherein the at least one etch opening is sealed.

12. The method according to claim 1, wherein the electrical contacting of the piezoresistive layer is provided before the formation of a cavity.

13. The method according to claim 1, wherein a protective layer of Si₃N₄, is provided to protect the piezoresistive layer.

14. The method according to claim 1, wherein, during the sealing of the etch openings, a defined internal pressure is produced in the cavities.

15. The method according to claim 1, wherein the insulation layer is formed on a supporting layer.

16. The method according to claim 9, wherein four piezoresistors are connected to form a Wheatstone bridge.

17. A Microelectromechanical element comprising:
an insulation layer;
a silicon layer; and
a patterned piezoresistive layer,
wherein, within the silicon layer, a cavity and above the cavity a self-supporting membrane are provided, on which are disposed at least parts of the piezoresistive, patterned layer.

18. The Microelectromechanical element according to claim 13, wherein a second insulation layer is disposed as a self-supporting membrane below the patterned piezoresistive layer.
